(19) United States
(12) Patent Application Publication
(10) Pub. No.: US 2026/0143810 A1
(43) Pub. Date: May 21, 2026

(54) SEMICONDUCTOR DEVICE

(71) Applicant: Samsung Electronics Co., Ltd., Suwon-si (KR)

(72) Inventors: Suk YANG, Suwon-si (KR); Soomin SON, Suwon-si (KR); Soyeong AHN, Suwon-si (KR); Sangmoon LEE, Suwon-si (KR)

(21) Appl. No.: 19/225,108

(22) Filed: Jun. 2, 2025

(30) Foreign Application Priority Data
Nov. 18, 2024 (KR) 10-2024-0164192

(51) Int. Cl. H10D 84/85; H10D 84/01; H10D 84/02

(52) U.S. Cl. CPC H10D 84/856; H10D 84/0167; H10D 84/017; H10D 84/02; H10D 84/851

(57) ABSTRACT

A semiconductor device includes a substrate, a first transistor disposed on the substrate and including first channel patterns stacked in a vertical direction, a first gate electrode surrounding each first channel pattern, and a first internal spacer on a side surface of the first gate electrode, and a second transistor stacked on the first transistor and comprising second channel patterns stacked in the vertical direction, a second gate electrode surrounding each second channel pattern, and a second internal spacer on a side surface of the second gate electrode. The first channel patterns and the second channel patterns include a two-dimensional material layer. A material of the first internal spacer is different from a material of the second internal spacer.

### CROSS-REFERENCE TO RELATED APPLICATION

This application is based on and claims priority to Korean Patent Application No. 10-2024-0164192, filed on Nov. 18, 2024 in the Korean Intellectual Property Office, the entire contents of which are hereby incorporated by reference.

### BACKGROUND

### Technical Field

The present disclosure relates to a semiconductor device.

### Description of the Related Art

Semiconductor devices can be used as components of electronic devices for storing data or controlling electrical signals, and various types of semiconductor devices can be manufactured for this purpose. For example, memory devices can be used primarily to store and retrieve data, while non-memory devices can be used to control or amplify electrical signals. Such semiconductor devices as key components of electronic devices are used in a variety of fields of computers, communications equipment, or consumer electronics.

As technology advances, the demand for improved performance and functionality in electronic devices continues to rise. To meet these expectations, it is desirable that semiconductor devices deliver high performance, and that their integration density is significantly increased. As a result, various methods have been explored to develop semiconductor devices that offer enhanced performance and improved integration.

### SUMMARY

The present disclosure has been made in an effort to provide a semiconductor device with improved reliability and integration.

According to an aspect of the present disclosure, a semiconductor device includes a substrate, a first transistor disposed on the substrate and including a plurality of first channel patterns stacked in a vertical direction perpendicular to an upper surface of the substrate, a first gate electrode surrounding each first channel pattern of the plurality of first channel patterns, a first internal spacer on a side surface of the first gate electrode and in a space between two adjacent first channel patterns, in the vertical direction, of the plurality of first channel patterns, and a first source/drain pattern adjacent to the plurality of first channel patterns in a horizontal direction parallel to the upper surface of the substrate, and a second transistor stacked on the first transistor in the vertical direction and comprising a plurality of second channel patterns stacked in the vertical direction, a second gate electrode surrounding each second channel pattern of the plurality of second channel patterns, a second internal spacer on a side surface of the second gate electrode and disposed in a space between two adjacent second channel patterns, in the vertical direction, of the plurality of second channel patterns, and a second source/drain pattern adjacent to the plurality of second channel patterns in the horizontal direction. The plurality of first channel patterns and the plurality of second channel patterns include a two-dimensional material layer. A material of the first internal spacer is different from a material of the second internal spacer.

According to an aspect of the present disclosure, a semiconductor device includes a substrate, a first transistor disposed on the substrate and comprising a plurality of first channel patterns stacked in a vertical direction perpendicular to an upper surface of the substrate, a first gate electrode surrounding each first channel pattern of the plurality of first channel patterns, and a first internal spacer on a side surface of the first gate electrode and in a space between two adjacent first channel patterns, in the vertical direction, of the plurality of first channel patterns, and a second transistor stacked on the first transistor in the vertical direction and comprising a plurality of second channel patterns stacked in the vertical direction, a second gate electrode surrounding each second channel pattern of the plurality of second channel patterns, and a second internal spacer on a side surface of the second gate electrode and in a space between two adjacent second channel patterns, in the vertical direction, of the plurality of second channel patterns. The plurality of first channel patterns and the plurality of second channel patterns comprise a two-dimensional material layer. A material of the first internal spacer is a first metal oxide and a material of the second internal spacer is a second metal oxide different from the first metal oxide.

According to an aspect of the present disclosure, a semiconductor device includes a substrate, a first transistor disposed on the substrate and comprising a plurality of first channel patterns stacked in a vertical direction perpendicular to an upper surface of the substrate, a first gate electrode surrounding each first channel pattern of the plurality of first channel patterns, a first internal spacer on a side surface of the first gate electrode and in a space between two adjacent first channel patterns, in the vertical direction, of the plurality of first channel patterns, and a first source/drain pattern adjacent to the plurality of first channel patterns in a horizontal direction parallel to the upper surface of the substrate, a second transistor stacked on the first transistor and comprising a plurality of second channel patterns stacked in the vertical direction, a second gate electrode surrounding each second channel pattern of the plurality of second channel patterns, a second internal spacer on a side surface of the second gate electrode and in a space between two adjacent second channel patterns, in the vertical direction, of the plurality of second channel patterns, and a second source/drain pattern adjacent to the plurality of second channel patterns in the horizontal direction, a first level isolation insulating film disposed in a space between the upper surface of the substrate and each of the first source/drain pattern, the first gate electrode, and the first internal spacer in the vertical direction, a second level isolation insulating film disposed in a space between the plurality of first channel patterns and the plurality of second channel patterns in the vertical direction, an interlayer insulating film disposed in a space between the first source/drain pattern and the second source/drain pattern in the vertical direction in the vertical direction, and a liner layer disposed in a space between the second level isolation insulating film and the interlayer insulating film in the horizontal direction. The plurality of first channel patterns and the plurality of second channel patterns comprise a two-dimensional material layer. The first internal spacer and the second internal spacer include different materials.

According to some embodiments of the present disclosure, the contact resistance of a semiconductor device may be reduced through an internal spacer disposed between a gate electrode and a source/drain pattern and including a material on which a charge transfer doping can be performed.

According to some embodiments of the present disclosure, the electrical contact area between a channel pattern and a source/drain pattern may increase through a vertical channel pattern, so that the contact resistance occurring at the contact surface may decrease, thereby improving the electrical performance of the device.

The effects of the present disclosure are not limited to those described above. The following description of the present disclosure would allow a person having ordinary skill in the art to clearly understand other technical effects thereof not mentioned above.

### BRIEF DESCRIPTION OF THE DRAWINGS

FIG. 1 is an exemplary plan view for illustrating a semiconductor device according to some embodiments of the present disclosure.

FIG. 2 shows a cross-section taken along line A-A in FIG. 1.

FIG. 3 shows a cross-section taken along line B-B in FIG. 1.

FIG. 4 is an enlarged view of region R1 in FIG. 2.

FIG. 5 is an enlarged view of region R2 in FIG. 2.

FIG. 6 is a view for illustrating a semiconductor device according to one embodiment of the present disclosure.

FIG. 7 is a view for illustrating the semiconductor device according to one embodiment of the present disclosure.

FIG. 8 is a view for illustrating a semiconductor device according to one embodiment of the present disclosure.

FIG. 9 is a view for illustrating a semiconductor device according to one embodiment of the present disclosure.

FIG. 10 is a view for illustrating a semiconductor device according to one embodiment of the present disclosure.

FIG. 11 is a view for illustrating a semiconductor device according to one embodiment of the present disclosure.

FIGS. 12 to 21 are views for illustrating intermediate steps of a method of manufacturing a semiconductor device according to some embodiments of the present disclosure.

### DETAILED DESCRIPTION

Hereinafter, with reference to the attached drawings, a semiconductor device and a method of manufacturing the same according to some embodiments of the present disclosure will be described in detail.

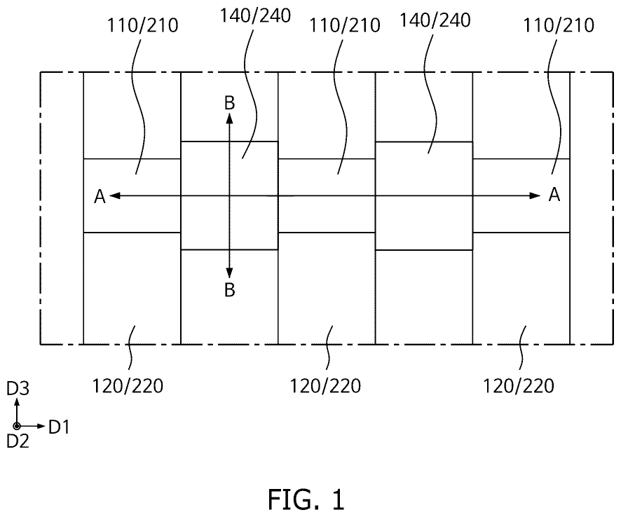

Hereinafter, in FIGS. 1 to 21, a first direction D1, a second direction D2, and a third direction D3 are perpendicular to each other, and the first direction D1 and the second direction D2, the second direction D2 and the third direction D3, and the first direction D1 and the third direction D3 form one plane, respectively. The second direction D2 is a vertical direction perpendicular to an upper surface of the substrate 100, the first direction D1 is a first horizontal direction parallel to the upper surface of the substrate 100, and the third direction D3 is a second horizontal direction different from the first horizontal direction.

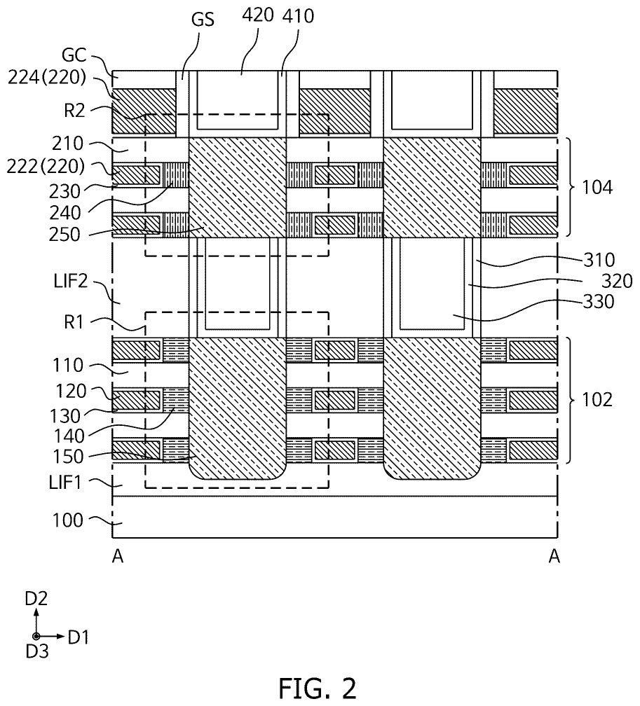

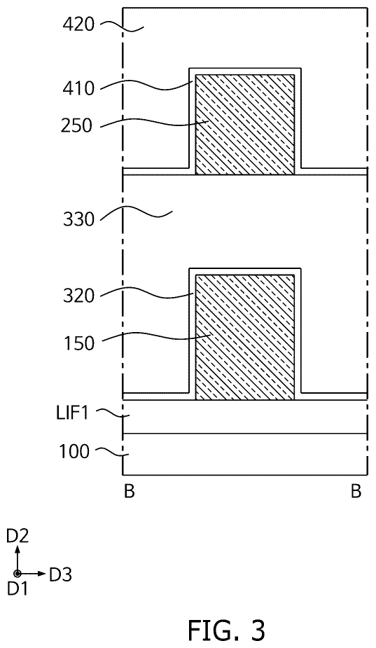

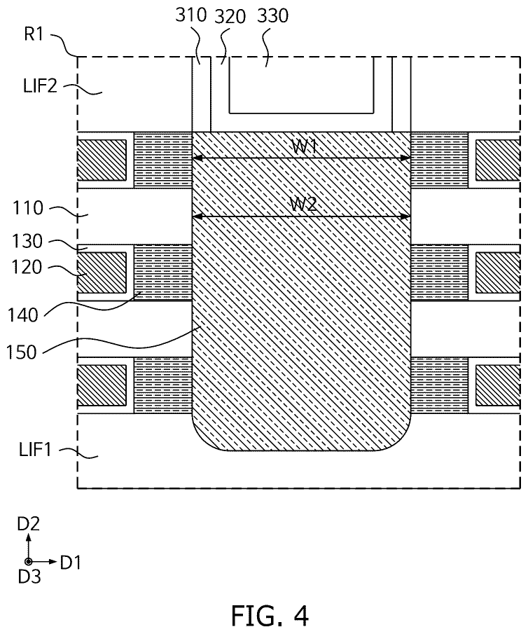

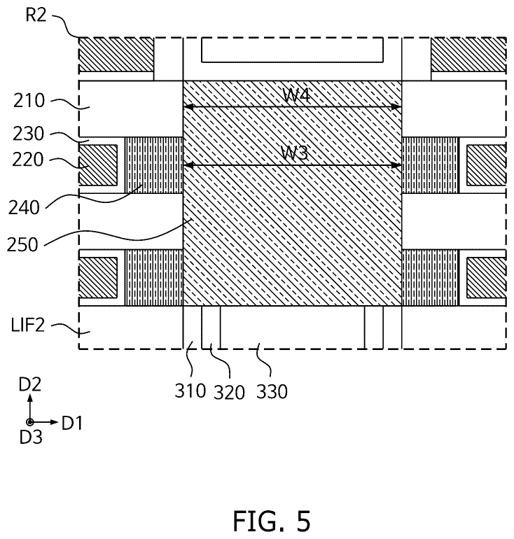

FIG. 1 is an exemplary plan view for illustrating a semiconductor device according to some embodiments of the present disclosure. FIG. 2 shows a cross-section taken along line A-A in FIG. 1. FIG. 3 shows a cross-section taken along line B-B in FIG. 1. FIG. 4 is an enlarged view of region R1 in FIG. 2. FIG. 5 is an enlarged view of region R2 in FIG. 2.

A semiconductor device according to some embodiments of the present disclosure may include a metal-oxide-semiconductor field-effect transistor (MOSFET), and, more specifically, a three-dimensional multi-stack semiconductor device referred to as a gate-all-around (GAA) transistor or a multi-bridge channel FET (MBCFET).

Referring to FIGS. 1 to 5, the semiconductor device according to some embodiments may include a substrate 100, a first device 102 (i.e., a first transistor), a second device 104 (i.e., a second transistor), a first level isolation insulating film LIF1, or a second level isolation insulating film LIF2.

The substrate 100 may be bulk silicon or silicon-on-insulator (SOI). In other embodiments, the substrate 100 may include silicon germanium (SiGe), silicon germanium on insulator (SGOI), indium antimonide, lead tellurium compound, indium arsenide, indium phosphide, gallium arsenide, or gallium antimonide, but the present disclosure is not limited thereto.

The first device 102 may include a plurality of first channel patterns 110 stacked in the vertical direction D2, a first gate electrode 120 surrounding each of the plurality of first channel patterns 110, a first internal spacer 140 arranged on at least one side of the first gate electrode 120 between the plurality of first channel patterns 110, and a first source/drain pattern 150 placed on at least one side of the plurality of first channel patterns 110. For example, the first internal spacer 140 may be in a space between a portion of the first gate electrode 120 and a side of the first source/drain pattern 150 in the first direction D1 parallel to the upper surface of the substrate 100, and may overlap the plurality of first channel patterns 110 in the second direction D2. The first source/drain pattern 150 may be adjacent to a side (i.e., a side surface) of each of the plurality of first channel patterns 110 in the first direction D1.

The second device 104 may be stacked on the first device 102. The second device 104 may include a plurality of second channel patterns 210 stacked in the second direction D2, a second gate electrode 220 surrounding each of the plurality of second channel patterns 210, a second internal spacer 240 arranged on at least one side of the second gate electrode 220 between the plurality of second channel patterns 210, and a second source/drain pattern 250 disposed on at least one side of the plurality of second channel patterns 210. For example, the second internal spacer 240 may be in a space between a portion of the second gate electrode 220 and a side of the second source/drain pattern 250 in the first direction D1, and may overlap the plurality of second channel patterns 210 in the second direction D2. The second source/drain pattern 250 may be adjacent to a side of each of the plurality of second channel patterns 210 in the first direction D1.

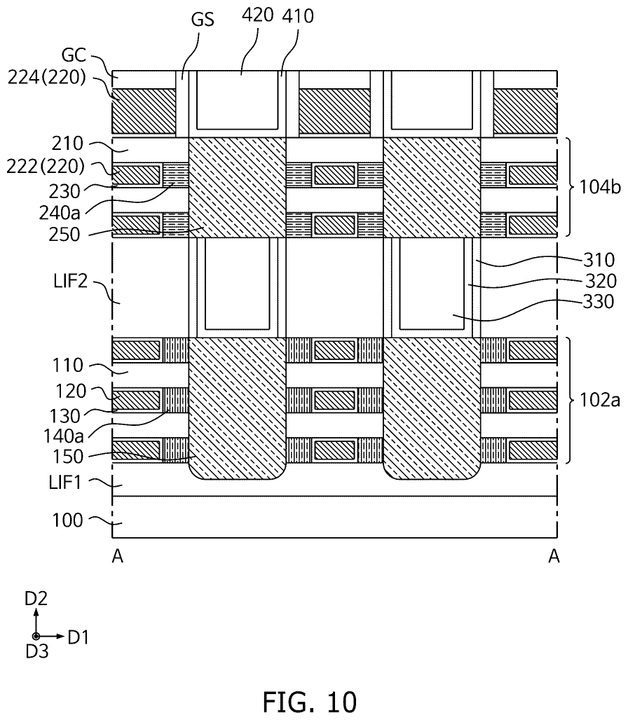

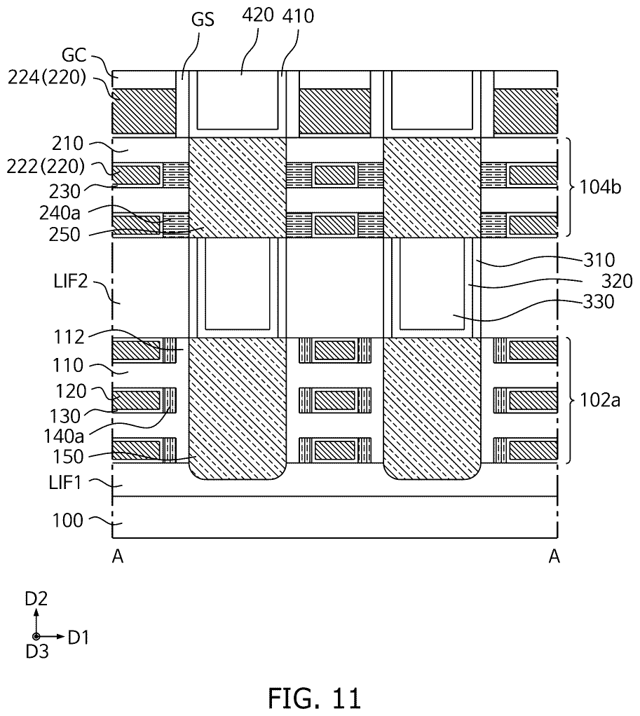

According to some embodiments of the present disclosure, the first device 102 may be an n-type device, and the second device 104 may be a p-type device. In other embodiments, the first device 102 may be a p-type device, and the second device 104 may be an n-type device. Hereinafter, for convenience of description, a semiconductor device where the first device 102 is an n-type device and the second device 104 is a p-type device will be described with reference to FIGS. 1 to 9, and a semiconductor device where the first device 102 is a p-type device (i.e., a p-type transistor) and the second device 104 is an n-type device (i.e., an n-type transistor) will be described with reference to FIGS. 10 and 11. However, the scope of the present disclosure is not limited thereto, and the first device 102 and the second device 104 may each be a p-type device or an n-type device.

The plurality of first channel patterns 110 may be arranged on the substrate 100. The plurality of first channel patterns 110 may be stacked spaced apart from each other in the vertical direction, e.g., the second direction D2. For example, the plurality of first channel patterns 110 may be a plurality of nanosheet patterns stacked in the second direction D2. For another example, the plurality of first channel patterns 110 may be a plurality of nanowire patterns stacked in the second direction D2.

The plurality of second channel patterns 210 may be spaced apart from the plurality of first channel patterns 110 in the second direction D2. The plurality of second channel patterns 210 may be stacked spaced apart from each other in the vertical direction, e.g., the second direction D2. For example, the plurality of second channel patterns 210 may be a plurality of nanosheet patterns stacked in the second direction D2. For another example, the plurality of second channel patterns 210 may be a plurality of nanowire patterns stacked in the second direction D2.

The first channel pattern 110 and the second channel pattern 210 may include a two-dimensional material layer. According to one embodiment, the first channel pattern 110 and the second channel pattern 210 may include a metal chalcogenide material. Specifically, the first channel pattern 110 and the second channel pattern 210 may include a transition metal dichalcogenide (TMD) material consisting of a transition metal and a chalcogen element. For example, the first channel pattern 110 and the second channel pattern 210 may include tungsten disulfide (WS₂), tungsten diselenide (WSe₂), molybdenum disulfide (MoS₂), or molybdenum diselenide (MoSe₂). However, the scope of the present disclosure is not limited thereto.

Although the plurality of first channel patterns 110 and the plurality of second channel patterns 210 each including two sheet patterns have been illustrated, the present disclosure is not limited thereto. Unlike what is illustrated, the plurality of first channel patterns 110 and the plurality of second channel patterns 210 may each include one or three or more sheet patterns. The plurality of first channel patterns 110 and the plurality of second channel patterns 210 may include different numbers of sheet patterns. For example, the plurality of first channel patterns 110 may include three sheet patterns, and the plurality of second channel patterns 210 may include two sheet patterns.

The first gate electrode 120 may surround each of the plurality of first channel patterns 110. The first gate electrode 120 may extend in the third direction D3 intersecting the second direction D2. For example, the first gate electrode 120 may extend lengthwise in the third direction D3 intersecting the second direction D2. The second gate electrode 220 may surround each of the plurality of second channel patterns 210. The second gate electrode 220 may extend in the third direction D3. For example, the second gate electrode 220 may extend lengthwise in the third direction D3. The second gate electrode 220 may include a lower region 222 adjacent to the second source/drain pattern 250 in the first direction D1 and an upper region 224 disposed on a side surface of a gate spacer GS.

The first gate electrode 120 and the second gate electrode 220 may include at least one of a metal, a metal alloy, a conductive metal nitride, a metal silicide, a doped semiconductor material, a conductive metal oxide, and a conductive metal oxynitride. For example, the first gate electrode 120 and the second gate electrode 220 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but the present disclosure is not limited thereto.

The first gate electrode 120 and the second gate electrode 220 being each a single film have been illustrated, but the present disclosure is not limited thereto. For example, at least one of the first gate electrode 120 and the second gate electrode 220 may include a work function control film that controls a work function of each of the first gate electrode 120 and the second gate electrode 220 and a filling conductive film that fills a space formed by the work function control film. The work function control film may include, for example, at least one of titanium nitride (TiN), tantalum carbide (TaC), tantalum nitride (TaN), titanium aluminum carbide (TiAlC), titanium carbide (TiC), and a combination thereof. The filling conductive film may include, for example, tungsten (W) or aluminum (Al).

In some embodiments, the first gate electrode 120 and the second gate electrode 220 may include different materials. Accordingly, an interface may appear between the first gate electrode 120 and the second gate electrode 220 at one end of the semiconductor device according to the present disclosure. However, the present disclosure is not limited thereto, and, even when the first gate electrode 120 and the second gate electrode 220 include different materials, no interface may appear between the first gate electrode 120 and the second gate electrode 220.

In some embodiments, the first gate electrode 120 and the second gate electrode 220 may include the same material. In this case, no interface may appear between the first gate electrode 120 and the second gate electrode 220.

A first gate insulating film 130 may be placed on the first gate electrode 120. For example, the first gate insulating film 130 may be arranged between the first gate electrode 120 and the first channel pattern 110. The first gate insulating film 130 may be disposed between the first gate electrode 120 and the first internal spacer 140 positioned on at least one side surface of the first gate electrode 120.

A second gate insulating film 230 may be placed on the second gate electrode 220. For example, the second gate insulating film 230 may be arranged between the second gate electrode 220 and the second channel pattern 210. The second gate insulating film 230 may be disposed between the second gate electrode 220 and the second internal spacer 240 positioned on at least one side surface of the second gate electrode 220.

Although the gate insulating film 130 and 230 being a single film has been illustrated, the present disclosure is not limited thereto. Unlike what is illustrated, the gate insulating film 130 and 230 may include a plurality of films. For example, the gate insulating film 130 and 230 may include a high-k insulating film and an interface insulating film.

The gate insulating films 130 and 230 may include, for example, silicon oxide, silicon oxynitride, silicon nitride, or a high-k material having a dielectric constant higher than that of silicon oxide. For example, the high-k material may include at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

A gate capping pattern GC may be disposed on an upper surface of the second gate electrode 220. For example, the gate capping pattern GC may cover the upper surface of the second gate electrode 220. The gate capping pattern GC may be placed between the gate spacers GS which are formed on opposite side surfaces of the upper portion 224 of the second gate electrode 220. A side surface of the gate capping pattern GC may contact the gate spacer GS. The term “contact,” as used herein, refers to a direct connection (i.e., physical touching) unless the context indicates otherwise.

The gate capping pattern GC may include, for example, at least one of silicon nitride (SiN), silicon oxynitride (SiON), silicon carbon nitride (SiCN), silicon oxycarbon nitride (SiOCN), and a combination thereof.

The gate spacer GS may be disposed on the upper region 224 of the second gate electrode 220 and the side surface of the gate capping pattern GC. The upper region 224 of the second gate electrode 220 may be arranged on the uppermost one of the plurality of second channel patterns 210. For example, the gate spacer GS may extend along a side surface of the upper region 224 of the second gate electrode 220 and the side surface of the gate capping pattern GC in the second direction D2.

The gate spacer GS may include at least one of, for example, silicon nitride (SiN), silicon oxynitride (SiON), silicon oxide (SiO2), silicon carbonitride (SiCN), silicon oxycarbon nitride (SiOCN), silicon boron nitride (SiBN), silicon oxyboron nitride (SiOBN), silicon oxycarbide (SiOC), and a combination thereof. The gate spacer GS being a single film has been illustrated only for convenience of description, and the present disclosure is not limited thereto.

Although not shown, a gate contact may be arranged in the gate capping pattern GC. The gate contact may penetrate the gate capping pattern GC in the second direction D2 and be electrically connected to the second gate electrode 220. The gate contact may include a conductive material.

The first internal spacer 140 may be arranged on a side surface of the first gate electrode 120. For example, the first internal spacer 140 may extend in the third direction D3 along a side surface of the first gate electrode 120 which is adjacent to the first internal spacer 140 in the first direction D1. The first internal spacer 140 may be placed between the plurality of first channel patterns 110. For example, the first internal spacer 140 may be disposed in a space between two adjacent first channel patterns of the plurality of first channel patterns 110 in the second direction D2. The first internal spacer 140 may be disposed on one surface, e.g., an upper surface, of the uppermost one of the plurality of first channel patterns 110 and/or may be positioned on one surface, e.g., a lower surface, of the lowermost one of the plurality of first channel patterns 110. Furthermore, the first internal spacer 140 may be placed in a space between the first gate electrode 120 and the first source/drain pattern 150 in the first direction D1.

In one embodiment, when the first device 102 is an n-type device, the first internal spacer 140 may include metal oxide such as aluminum oxide (Al₂O₃). However, the scope of the present disclosure is not limited thereto, and the first internal spacer 140 may include metal oxide including, for example, hafnium oxide (HfO₂), zirconium oxide (ZrO₂), tantalum oxide (Ta₂O₃), or titanium oxide (TiO₂). The materials disclosed herein are not limited to the exemplified stoichiometric compositions.

The second internal spacer 240 may be positioned on a side surface of the second gate electrode 220. For example, the second internal spacer 240 may extend in the third direction D3 along a side surface of the second gate electrode 220 which is adjacent to the second internal spacer 240 in the first direction D1. The second internal spacer 240 may be disposed on one surface, e.g., an upper surface, of the uppermost one of the plurality of second channel patterns 210 and/or may be arranged on one surface, e.g., a lower surface, of the lowermost one of the plurality of second channel patterns 210. Furthermore, the second internal spacer 240 may be disposed between the second gate electrode 220 and the second source/drain pattern 250.

In one embodiment, when the second device 104 is a p-type device, the second internal spacer 240 may include metal oxide such as tungsten oxide (WO₃) or molybdenum oxide (MoO₃). However, the scope of the present disclosure is not limited thereto, and the second internal spacer 240 may include metal oxide including, for example, silicon oxide (SiO₂), silicon nitride (Si₃N₄), hafnium silicate (HfSiO₄), or aluminum oxide (Al₂O₃). The first internal spacer and the second internal spacer may include different materials, and are not intended to be formed of the same material.

The first source/drain pattern 150 may be arranged on a side surface of the first channel pattern 110. For example, the first source/drain pattern 150 may be disposed on a side surface in the first direction D1 of the first channel pattern 110 and the first internal spacer 140 that is cross-stacked with the first channel pattern 110. For example, the first internal spacer 140 and the first channel pattern 110 may be alternately stacked in the second direction D2.

The internal spacers 140 and 240 (i.e., charge-transfer-doping layers) positioned between the gate electrode 120 and 220 and the source/drain pattern 150 and 250 may include a material for which charge transfer doping can be performed. The charge transfer doping is a non-destructive, non-implant-based technique where a doping effect is achieved by placing a material layer such as the internal spacer 140 and 240 near a channel pattern such as the first channel pattern 110 and the second channel pattern 210 that transfer charges (electrons or holes) into it via work function difference or chemical potential interaction between the material layer and the channel pattern. For example, tungsten oxide (WO₃) has a high work function, which can align with the valence band of the underlying semiconductor (e.g., silicon nanowire or nanosheet). When tungsten oxide is deposited adjacent to the channel pattern of a p-type transistor the internal spacer, its Fermi level can induce band bending in the channel pattern, resulting in charge transfer (e.g., hole transfer) to the channel pattern. With the other metal oxide listed in the disclosure, the similar charge transfer mechanism may apply. For a n-type transistor, electron transfer may happen from a metal oxide, as listed in the disclosure, of an internal spacer to a channel pattern. As a result, the contact resistance of the first device 102 and the second device 104 may be reduced.

According to one embodiment, the first source/drain pattern 150 may have a constant width in the first direction D1. Here, the width of the first source/drain pattern 150 may refer to a distance between opposite side surfaces of the first source/drain pattern 150 in the first direction D1. Referring to FIG. 4, the first source/drain pattern 150 may have a first width W1 at a vertical level corresponding to the first gate electrode 120 and a second width W2 at a vertical level corresponding to the first channel pattern 110. In this case, the first width W1 and the second width W2 may be substantially identical to each other. Terms such as “same,” “equal,” “planar,” “identical,” or “coplanar,” as used herein encompass near identicality including variations that may occur, for example, due to manufacturing processes. The term “substantially” may be used herein to emphasize this meaning, unless the context or other statements indicate otherwise.

The second source/drain pattern 250 may be arranged on a side surface of the second channel pattern 210. For example, the second source/drain pattern 250 may be placed on a side surface in the first direction D1 of the second channel pattern 210 and the second internal spacer 240 that is cross-stacked with the second channel pattern 210. For example, the second internal spacer 240 and the second channel pattern 210 may be alternately stacked in the second direction D2.

According to one embodiment, the second source/drain pattern 250 may have a constant width in the first direction D1. Here, the width of the second source/drain pattern 250 may refer to a distance between opposite side surfaces of the second source/drain pattern 250 in the first direction D1. Referring to FIG. 5, the second source/drain pattern 250 may have a third width W3 at a vertical level corresponding to the second gate electrode 220 and a fourth width W4 at a vertical level corresponding to the second channel pattern 210. In this case, the third width W3 and the fourth width W4 may be substantially identical to each other.

The first source/drain pattern 150 and the second source/drain pattern 250 may include at least one of a metal, a metal alloy, a conductive metal nitride, a metal silicide, a doped semiconductor material, a conductive metal oxide, and a conductive metal oxynitride. For example, the first source/drain pattern 150 and the second source/drain pattern 250 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but the present disclosure is not limited thereto.

Only the first source/drain pattern 150 and the second source/drain pattern 250 being each a single film have been illustrated, but the present disclosure is not limited thereto. For example, the first source/drain pattern 150 and the second source/drain pattern 250 may include a liner contacting the first channel pattern 110 and the first internal spacer 140 and a filling conductive film adjacent to the liner. The liner may include, for example, at least one of titanium nitride (TiN), tantalum carbide (TaC), tantalum nitride (TaN), titanium aluminum carbide (TiAlC), titanium carbide (TiC), and a combination thereof. The filling conductive film may include, for example, tungsten (W) or aluminum (Al).

The first level isolation insulating film LIF1 may be placed in a space between the substrate 100 and the first device 102 in the second direction D2. For example, the first level isolation insulating film LIF1 may be positioned on the substrate 100, and the first device 102 may be arranged on the first level isolation insulating film LIF1. The first level isolation insulating film LIF1 may be disposed on the first source/drain pattern 150, the first gate electrode 120, and the first internal spacer 140. For example, the first level isolation insulating film LIF1 may contact the first source/drain pattern 150, the first gate electrode 120, and the first internal spacer 140.

The first level isolation insulating film LIF1 may include an insulating material. Although not shown, the semiconductor device according to some embodiments may further include a lower gate contact penetrating the first level isolation insulating film LIF1 and the substrate 100. In this case, the substrate 100 may be an insulating substrate including an insulating material.

The second level isolation insulating film LIF2 may be placed in a space between the first device 102 and the second device 104 in the second direction D2. For example, the second level isolation insulating film LIF2 may be disposed between the plurality of first channel patterns 110 and the plurality of second channel patterns 210. For example, the second level isolation insulating film LIF2 may be arranged on the first gate electrode 120 surrounding each of the plurality of first channel patterns 110. The second level isolation insulating film LIF2 may include an insulating material.

A liner layer 310 may be disposed on a side surface of the second level isolation insulating film LIF2. For example, the liner layer 310 may be placed on a side surface in the first direction D1 of the second level isolation insulating film LIF2. The liner layer 310 may be arranged between the second level isolation insulating film LIF2 and a first interlayer insulating film 330. In one embodiment, the liner layer 310 may be disposed between the second level isolation insulating film LIF2 and a first etching stop film 320 positioned on a side surface of the first interlayer insulating film 330. In another embodiment, the liner layer 310 may be arranged in a space between the second level isolation insulating film LIF2 and the first interlayer insulating film 330 in the horizontal direction. The liner layer 310 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof.

The first etching stop film 320 may be disposed on an upper surface of the first source/drain pattern 150 and on a side surface in the first direction D1 of the liner layer 310. For example, the first etching stop film 320 may extend in the second direction D2 along the liner layer 310 from opposite ends in the first direction D1 of the upper surface of the first source/drain pattern 150 to a lower surface of the second source/drain pattern 250. The first etching stop film 320 may be placed on a side surface in the third direction D3 of the first source/drain pattern 150. For example, the first etching stop film 320 may be placed on an upper surface of the first source/drain pattern 150. In an embodiment, the first etching stop film 320 may be a U-shape film which contacts the upper surface of the first source/drain pattern 150 and the liner layer 310.

A second etching stop film 410 may be disposed on an upper surface of the second source/drain pattern 250 and on a side surface in the first direction D1 of the gate spacer GS. For example, the second etching stop film 410 may extend upwardly in the second direction D2 along the gate spacer GS from opposite ends in the first direction D1 of the upper surface of the second source/drain pattern 250. The second etching stop film 410 may be placed on a side surface in the third direction D3 of the second source/drain pattern 250. For example, the second etching stop film 410 may be placed on an upper surface of the second source/drain pattern 250. In an embodiment, the second etching stop film 410 may be a U-shape film which contacts the upper surface of the second source/drain pattern 250 and the gate spacer GS.

Each of the first etching stop film 320 and the second etching stop film 410 may include, for example, at least one of silicon nitride (SiN), silicon oxide (SiO), silicon oxynitride (SiON), silicon oxycarbonitride (SiOCN), silicon boron nitride (SiBN), silicon oxyboron nitride (SiOBN), silicon oxycarbide (SiOC), and a combination thereof.

The first interlayer insulating film 330 may be placed in a space between the first source/drain pattern 150 and the second source/drain pattern 250 in the second direction D2. The first interlayer insulating film 330 may be disposed on the first source/drain pattern 150.

The first interlayer insulating film 330 may include, for example, at least one of silicon oxide (SiO), silicon nitride (SiN), silicon oxynitride (SiON), and a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but the present disclosure is not limited thereto.

A second interlayer insulating film 420 may be disposed on the first interlayer insulating film 330 and the second source/drain pattern 250. The second interlayer insulating film 420 may include, for example, at least one of silicon oxide (SiO), silicon nitride (SiN), silicon oxynitride (SiON), and a low-k material. The low-k material may include the materials described in relation to the first interlayer insulating film 330, and the description thereof will not be repeated.

In some embodiments, the second etching stop film 410 may be placed between the second interlayer insulating film 420 and the first interlayer insulating film 330. In this case, the second etching stop film 410 may be arranged in a direction parallel to one surface of the substrate 100, e.g., the first direction D1 and the third direction D3, along an interface between the second interlayer insulating film 420 and the first interlayer insulating film 330.

In some embodiments, the second interlayer insulating film 420 and the first interlayer insulating film 330 may be formed as one single piece. In this case, no interface may appear between the second interlayer insulating film 420 and the first interlayer insulating film 330.

Although not shown, the semiconductor device according to some embodiments of the present disclosure may have an upper conductive contact disposed on the second source/drain pattern 250. The upper conductive contact may be electrically connected to the second source/drain pattern 250. In other embodiments, a lower conductive contact may be placed on the first source/drain pattern 150 of the semiconductor device. The lower conductive contact may be electrically connected to the first source/drain pattern 150.

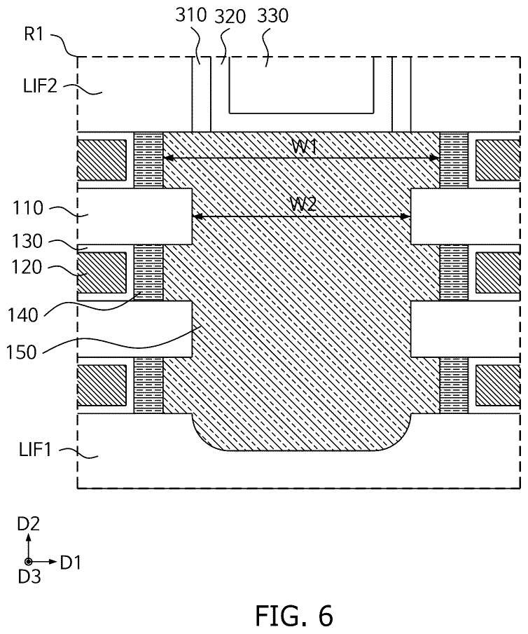

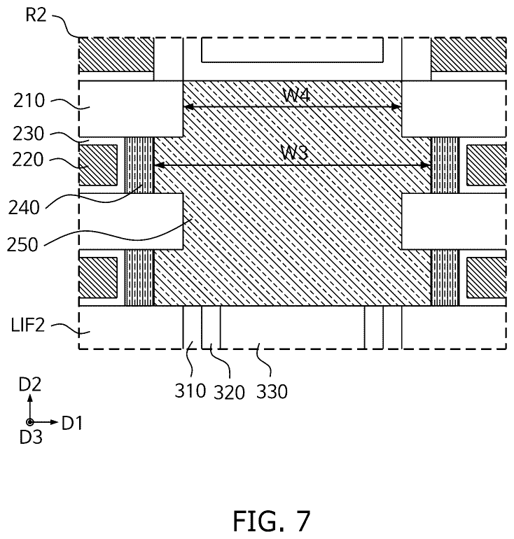

FIGS. 6 and 7 are views for illustrating a semiconductor device according to one embodiment of the present disclosure. FIG. 6 is an enlarged view of region R1 in FIG. 2. FIG. 7 is an enlarged view of region R2 in FIG. 2. The semiconductor device in FIGS. 6 and 7 may be substantially identical to the semiconductor device described with reference to FIGS. 1 to 5, except for the shape of the first source/drain pattern 150 and/or the second source/drain pattern 250. Hereinafter, for convenience of description, components other than those described with reference to FIGS. 1 to 5 will be mainly described.

According to one embodiment, the first source/drain pattern 150 may have different widths extending in the first direction D1 at different vertical levels. Here, the width of the first source/drain pattern 150 may refer to a distance between the two sides in the first direction D1. Referring to FIG. 6, the first source/drain pattern 150 may have a first width W1 at a vertical level corresponding to the first gate electrode 120 and a second width W2 at a vertical level corresponding to the first channel pattern 110, and, in this case, the first width W1 may be larger than the second width W2. That is, the distance between the two sides of the first source/drain pattern 150 in the first direction D1 at the vertical level corresponding to the first gate electrode 120 may be greater than the distance between the two sides of the first source/drain pattern 150 in the first direction D1 at the vertical level corresponding to the first channel pattern 110. In an embodiment, the first source/drain pattern 150 may include a first portion, which may have the first width W1 at a first vertical level corresponding to the corresponding portion of the first gate electrode 120, and a second portion, which may have the second width W2 at a second vertical level corresponding to the corresponding first channel pattern of the plurality of first channel patterns 110, and the first width W1 may be larger than the second width W2. The first portion and the corresponding portion of the first gate electrode 120 may be adjacent to each other in the horizontal direction at the first vertical level, and the second portion and the corresponding first channel pattern 110 may be adjacent to each other in the horizontal direction at the second vertical level.

The first channel pattern 110 may protrude further than the first internal spacer 140 toward the first source/drain pattern 150 in the first direction D1. The width of the first channel pattern 110 in the first direction D1 may be larger than the width between outer side surfaces of the first internal spacers 140 formed on opposite sides of the first gate electrode 120. A side surface of the first source/drain pattern 150 at the vertical level corresponding to the first gate electrode 120 may be misaligned in the second direction D2 with a side surface of the first source/drain pattern 150 at the vertical level corresponding to the first channel pattern 110. The first channel pattern 110 may overlap the first source/drain pattern 150 in the second direction D2.

According to one embodiment, the second source/drain pattern 250 may have different widths extending in the first direction D1 at different vertical levels. Here, the width of the second source/drain pattern 250 may refer to a distance between the two side surfaces in the first direction D1 of the second source/drain pattern 250. Referring to FIG. 7, the second source/drain pattern 250 may have a third width W3 at a vertical level corresponding to the second gate electrode 220 and a fourth width W4 at a vertical level corresponding to the second channel pattern 210, and, in this case, the third width W3 may be larger than the fourth width W4. That is, the distance between the two sides in the first direction D1 of the second source/drain pattern 250 at the vertical level corresponding to the second gate electrode 220 may be greater than the distance between the two sides in the first direction D1 of the second source/drain pattern 250 at the vertical level corresponding to the second channel pattern 210. In an embodiment, the second source/drain pattern 250 may include a first portion, which may have the third width W3 at a first vertical level corresponding to the corresponding portion of the second gate electrode 220, and a second portion, which may have the fourth width W4 at a second vertical level corresponding to the corresponding second channel pattern of the plurality of second channel patterns 210, and the third width W3 may be larger than the fourth width W4. The first portion and the corresponding portion of the second gate electrode 220 may be adjacent to each other in the horizontal direction at the first vertical level, and the second portion and the corresponding second channel pattern 210 may be adjacent to each other in the horizontal direction at the second vertical level.

The second channel pattern 210 may protrude further than the second internal spacer 240 toward the second source/drain pattern 250 in the first direction D1. The width of the second channel pattern 210 in the first direction D1 may be larger than the width between outer side surfaces of the second internal spacers 240 formed on opposite sides of the second gate electrode 220. A side surface of the second source/drain pattern 250 at the vertical level corresponding to the second gate electrode 220 may be misaligned in the second direction D2 with a side surface of the second source/drain pattern 250 at the vertical level corresponding to the second channel pattern 210. The second channel pattern 210 may overlap the second source/drain pattern 250 in the second direction D2.

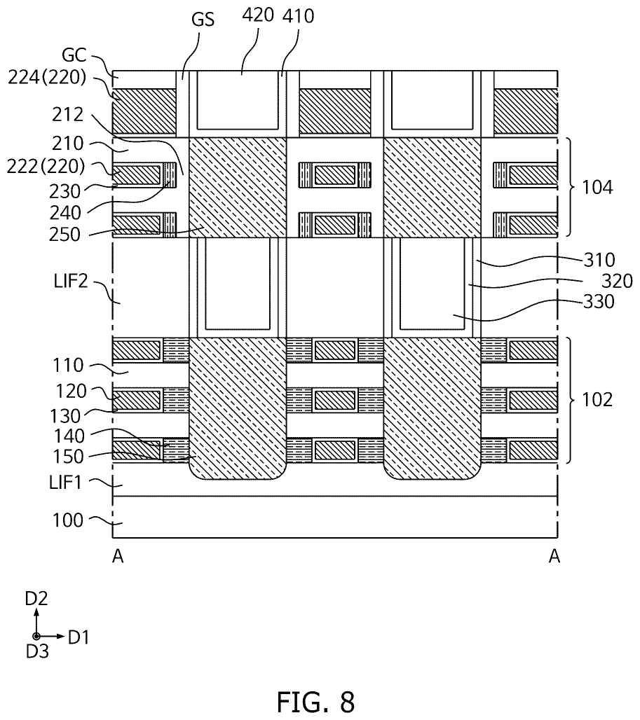

FIG. 8 is a view for illustrating a semiconductor device according to one embodiment of the present disclosure. The semiconductor device in FIG. 8 may be substantially identical to the semiconductor device described with reference to FIGS. 1 to 7, except that the second device 104 further includes a first vertical channel pattern 212. Hereinafter, for convenience of description, components other than those described with reference to FIGS. 1 to 7 will be mainly described.

According to one embodiment, when the second device 104 is a p-type device, it may further include the first vertical channel pattern 212 disposed between the second source/drain pattern 250 and the second internal spacer 240. In an embodiment, the first vertical channel pattern 212 may be disposed in a space between the second source/drain pattern 250 and the second internal spacer 240 in the horizontal direction. In an embodiment, the first vertical channel pattern 212 may extend in the second direction D2. The first vertical channel pattern 212 is arranged at the end of the plurality of second channel patterns 210 and may be placed on a side surface of the second internal spacer 240 between the plurality of second channel patterns 210.

The first vertical channel pattern 212 may include a two-dimensional material layer. According to one embodiment, the first vertical channel pattern 212 may include a metal chalcogenide material. Specifically, the first vertical channel pattern 212 may include a transition metal dichalcogenide (TMD) material consisting of a transition metal and a chalcogen element. For example, the first vertical channel pattern 212 may include tungsten disulfide (WS₂), tungsten diselenide (WSe₂), molybdenum disulfide (MoS₂), or molybdenum diselenide (MoSe₂). However, the scope of the present disclosure is not limited thereto. In one embodiment, the first vertical channel pattern 212 may include the same material as that of the plurality of second channel patterns 210. Accordingly, the plurality of second channel patterns 210 and the first vertical channel pattern 212 may be formed as one single piece.

As a result, the electrical contact area between the second channel pattern 210 and the second source/drain pattern 250 of the second device 104 may increase so that the contact resistance occurring at the contact surface is reduced, thereby improving the electrical performance of the semiconductor device.

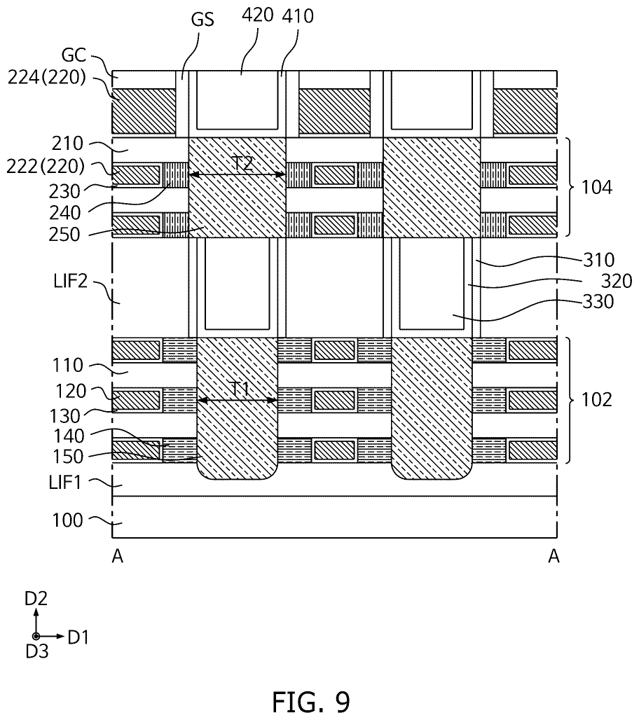

FIG. 9 is a view for illustrating a semiconductor device according to one embodiment of the present disclosure. The semiconductor device in FIG. 9 may be substantially identical to the semiconductor device described with reference to FIGS. 1 to 8, except for the shapes of the first source/drain pattern 150 and the second source/drain pattern 250. Hereinafter, for convenience of description, components other than those described with reference to FIGS. 1 to 8 will be mainly described.

According to one embodiment, a width T1 of the first source/drain pattern 150 may be smaller than a width T2 of the second source/drain pattern 250. The length of the first channel pattern 110 may be longer than the length of the second channel pattern 210. Here, the widths T1 and T2 of the first source/drain pattern 150 and the second source/drain pattern 250 may each refer to a distance between the two sides in the first direction D1. The widths T1 and T2 of the first source/drain pattern 150 and the second source/drain pattern 250 may each refer to an average width at the entire vertical level.

On the other hand, the widths T1 and T2 of the first source/drain pattern 150 and the second source/drain pattern 250 may refer to widths at vertical levels corresponding to each other. For example, the width T1 of the first source/drain pattern 150 may refer to a distance between opposite sides in the first direction D1 at a vertical level corresponding to a vertical level of the first channel pattern 110, and the width T2 of the second source/drain pattern 250 may refer to a distance between opposite sides in the first direction D1 at a vertical level corresponding to a vertical level of the second channel pattern 210. For another example, the width T1 of the first source/drain pattern 150 may refer to a distance between opposite sides in the first direction D1 at a vertical level corresponding to a vertical level of the first gate electrode 120, and the width T2 of the second source/drain pattern 250 may refer to a distance between opposite sides in the first direction D1 at a vertical level corresponding to a vertical level of the second gate electrode 220.

According to one embodiment, the difference between the width T1 of the first source/drain pattern 150 and the width T2 of the second source/drain pattern 250 may correspond to the width or thickness in the first direction D1 of the liner layer 310. However, the scope of the present disclosure is not limited thereto.

The first internal spacer 140 may overlap the liner layer 310 in the second direction D2. The second internal spacer 240 may not overlap the liner layer 310 in the second direction D2. The first source/drain pattern 150 may not overlap the liner layer 310 in the second direction D2. The second source/drain pattern 250 may overlap the liner layer 310 in the second direction D2.

FIG. 10 is a view for illustrating a semiconductor device according to one embodiment of the present disclosure. The semiconductor device in FIG. 10 may be substantially identical to the semiconductor device described with reference to FIGS. 1 to 7 and 9, except that a first device 102a is a p-type device and a second device 104b is an n-type device. Hereinafter, for convenience of description, components other than those described with reference to FIGS. 1 to 7 and 9 will be mainly described.

In the case of the semiconductor device according to one embodiment of the present disclosure, the first device 102a may be a p-type device, and the second device 104b may be an n-type device. In this case, a first internal spacer 140a may include tungsten oxide (WO₃) or molybdenum oxide (MoO₃). However, the scope of the present disclosure is not limited thereto, and the first internal spacer 140a may include, for example, silicon oxide (SiO₂), silicon nitride (Si₃N₄), hafnium silicate (HfSiO₄), or aluminum oxide (Al₂O₃). The second internal spacer 240a may include aluminum oxide (Al₂O₃). However, the scope of the present disclosure is not limited thereto, and the second internal spacer 240a may include, for example, hafnium oxide (HfO₂), zirconium oxide (ZrO₂), tantalum oxide (Ta₂O₃), or titanium oxide (TiO₂). The first internal spacer and the second internal spacer may include different materials, and are not intended to be formed of the same material.

FIG. 11 is a view for illustrating a semiconductor device according to one embodiment of the present disclosure. The semiconductor device in FIG. 11 may be substantially identical to the semiconductor device described with reference to FIG. 10, except that the first device 102a further includes a second vertical channel pattern 112. Hereinafter, for convenience of description, components other than those described with reference to FIGS. 1 to 7, 9, and 10 will be mainly described.

According to one embodiment, when the first device 102a is a p-type device, it may further include the second vertical channel pattern 112 disposed between the first source/drain pattern 150 and the first internal spacer 140a. In an embodiment, the second vertical channel pattern 112 may be disposed in a space between the first source/drain pattern 150 and the first internal spacer 140a in the horizontal direction. In an embodiment, the second vertical channel pattern 112 may extend in the second direction D2. The second vertical channel pattern 112 may be arranged at the end of the plurality of first channel patterns 110 and may be placed on a side surface of the first internal spacer 140a between the plurality of first channel patterns 110.

The second vertical channel pattern 112 may include a two-dimensional material layer. According to one embodiment, the second vertical channel pattern 112 may include a metal chalcogenide material. Specifically, the second vertical channel pattern 112 may include a transition metal dichalcogenide (TMD) material consisting of a transition metal and a chalcogen element. For example, the second vertical channel pattern 112 may include tungsten disulfide (WS₂), tungsten diselenide (WSe₂), molybdenum disulfide (MoS₂), or molybdenum diselenide (MoSe₂). However, the scope of the present disclosure is not limited thereto. In one embodiment, the second vertical channel pattern 112 may include the same material as that of the plurality of first channel patterns 110. Accordingly, the plurality of first channel patterns 110 and the second vertical channel pattern 112 may be formed as one single piece.

As a result, the electrical contact area between the first channel pattern 110 and the first source/drain pattern 150 of the first device 102a may be expanded, so that the contact resistance occurring at the contact surface may be reduced, thereby improving the electrical performance of the semiconductor device.

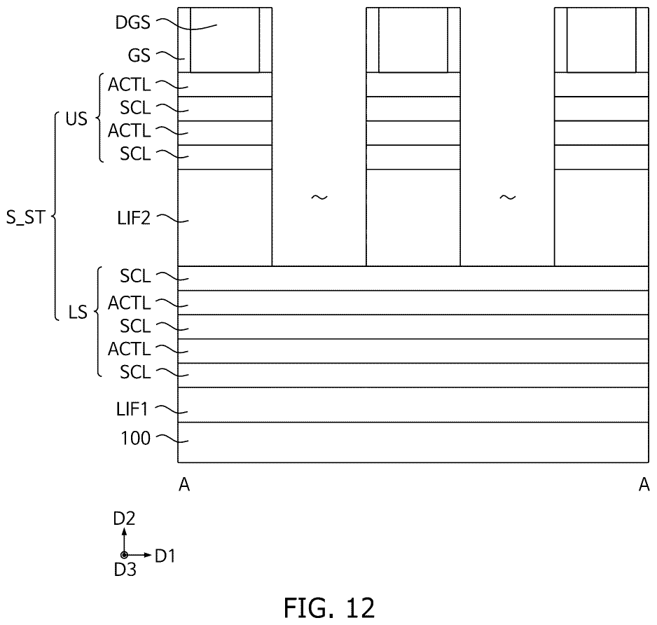

FIGS. 12 to 21 are views for illustrating intermediate steps of a method of manufacturing a semiconductor device according to some embodiments of the present disclosure. For reference, FIGS. 12 to 21 are views of cross-sections corresponding to a cross-section taken along line A-A in FIG. 1.

Referring to FIG. 12, the method of manufacturing a semiconductor device according to some embodiments may include forming a patterned stacked structure S_ST on the substrate 100.

The substrate 100 may be a silicon substrate, or may include other materials, such as silicon germanium (SiGe), silicon germanium on insulator (SGOI), indium antimonide, lead tellurium compound, indium arsenide, indium phosphide, gallium arsenide, or gallium antimonide. However, the present disclosure is not limited thereto.

First, the first level isolation insulating film LIF1 may be formed on the substrate 100. Next, the stacked structure S_ST may be formed on the first level isolation insulating film LIF1. The stacked structure S_ST may include sacrificial semiconductor layers SCL and active semiconductor layers ACTL, which are alternately stacked. Here, the active semiconductor layer ACTL may include a two-dimensional material layer. As illustrated, the stacked structure S_ST may include a stacked upper structure US, a stacked lower structure LS, and a second level isolation insulating film LIF2 between the stacked upper structure US and the stacked lower structure LS. The stacked upper structure US may be defined as a stacked structure including the active semiconductor layers ACTL and the sacrificial semiconductor layers SCL, arranged on the second level isolation insulating film LIF2. The stacked lower structure LS may be defined as a stacked structure including the active semiconductor layers ACTL and the sacrificial semiconductor layers SCL, arranged under the second level isolation insulating film LIF2. The active semiconductor layer ACTL and the sacrificial semiconductor layer SCL may be formed of materials with different etching selectivity.

A dummy gate structure DGS may be formed on the stacked structure S_ST. The gate spacer GS may be formed on a side surface of the dummy gate structure DGS.

Next, a portion of the stacked structure S_ST may be patterned, that is, selectively removed, using a mask pattern which is formed on the stacked structure S_ST. Specifically, the portion from an upper surface of the stacked structure S_ST to an upper surface of the stacked lower structure LS may be patterned into the shape of a fin. Although, in the drawing, the patterned portion of the stacked structure S_ST has a constant thickness in the second direction D2, it may have an inclined side surface so that the thickness increases toward the substrate 100.

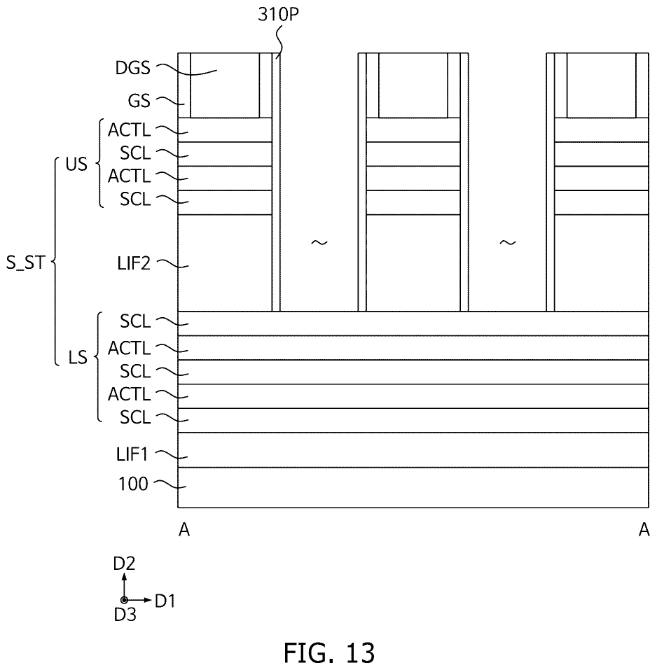

Referring to FIG. 13, a preliminary liner layer 310P may be formed on a trench sidewall (i.e., a trench side surface) formed between the stacked structures S_ST, which have been patterned. For example, the preliminary liner layer 310P may be formed on a sidewall of the gate spacer GS, the stacked upper structure US, and the second level isolation insulating film LIF2. In an embodiment, the mask pattern may remain after the formation of the stacked structures S_ST of FIG. 12, and the preliminary liner layer 310P may be formed on the mask pattern. In an embodiment, the mask pattern may be removed after the formation of the stacked structures S_ST of FIG. 12, and then the preliminary liner layer 310P may be formed on an upper surface of the dummy gate structure DGS.

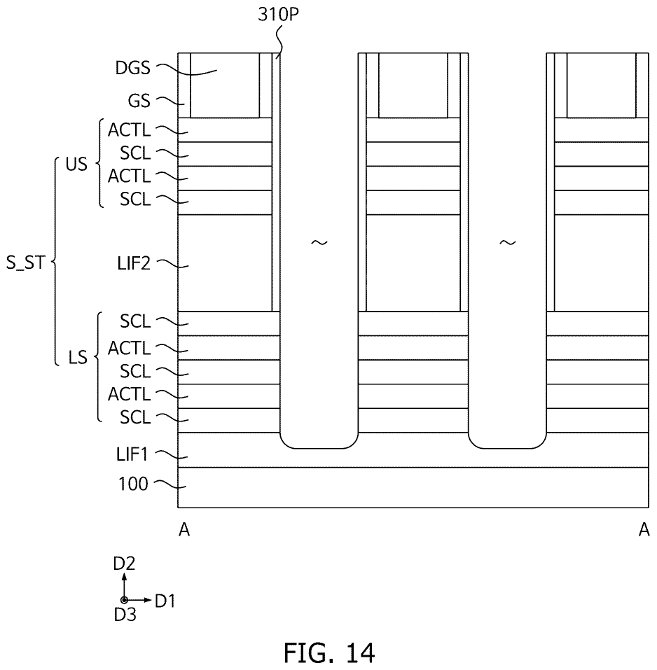

Referring to FIG. 14, the stacked lower structure LS may be patterned using a mask pattern, resulting in the stacked structures S_ST patterned in the shape of a fin. In an embodiment, the stacked lower structure LS may be patterned using the preliminary liner layer 310P as an etch mask.

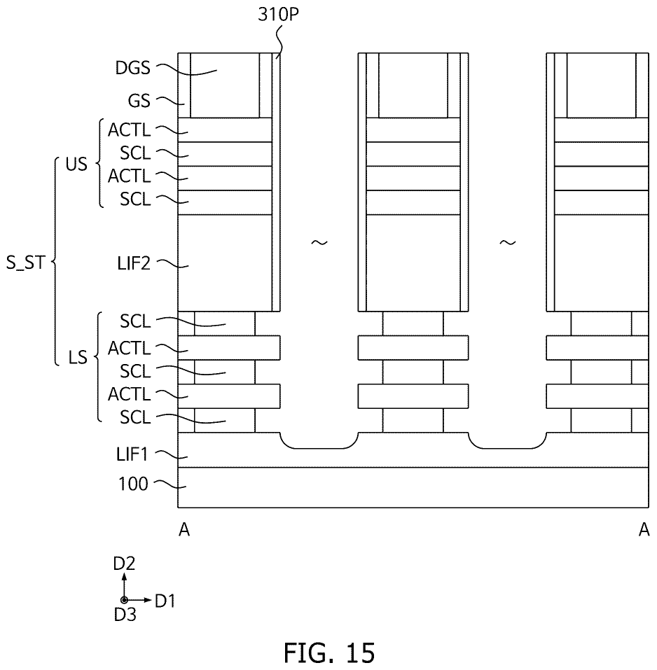

Referring to FIG. 15, a part of a side surface of the sacrificial semiconductor layer SCL of the stacked lower structure LS may be selectively removed. Opposite side surfaces of the sacrificial semiconductor layer SCL of the stacked lower structure LS may be partially patterned in the first direction D1.

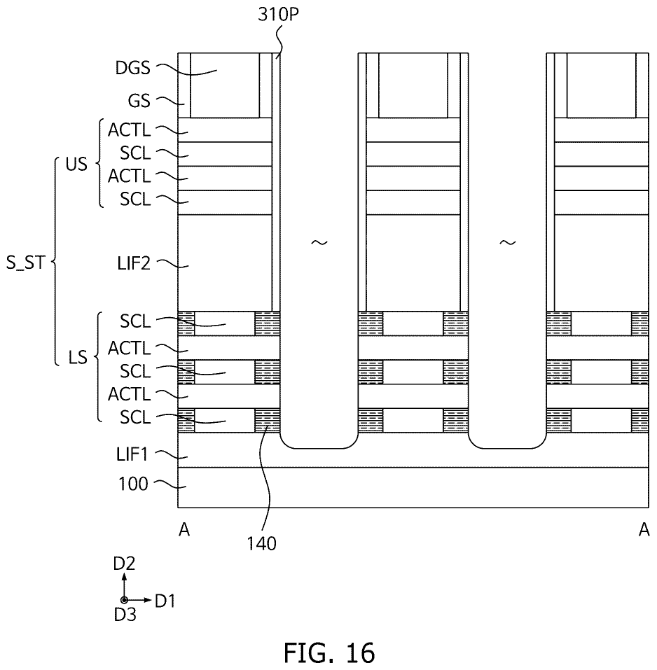

Referring to FIG. 16, the first internal spacer 140 may be formed in a space formed by patterning the sacrificial semiconductor layer SCL of the stacked lower structure LS in the first direction D1. The drawing shows an example in which a side surface of the first internal spacer 140 and a side surface of the active semiconductor layer ACTL of the stacked lower structure LS are aligned with each other in the second direction D2, but the scope of the present disclosure is not limited thereto. For example, the side surface of the first internal spacer 140 may be formed at a position in the first direction D1 away from the position of the side surface of the active semiconductor layer ACTL of the stacked lower structure LS. Here, the first internal spacer 140 may include aluminum oxide (Al₂O₃), hafnium oxide (HfO₂), zirconium oxide (ZrO₂), tantalum oxide (Ta₂O₃), or titanium oxide (TiO₂). In other embodiments, the first internal spacer 140 may include tungsten oxide (WO₃), molybdenum oxide (MoO₃), silicon oxide (SiO₂), silicon nitride (Si₃N₄), hafnium silicate (HfSiO₄), or aluminum oxide (Al₂O₃).

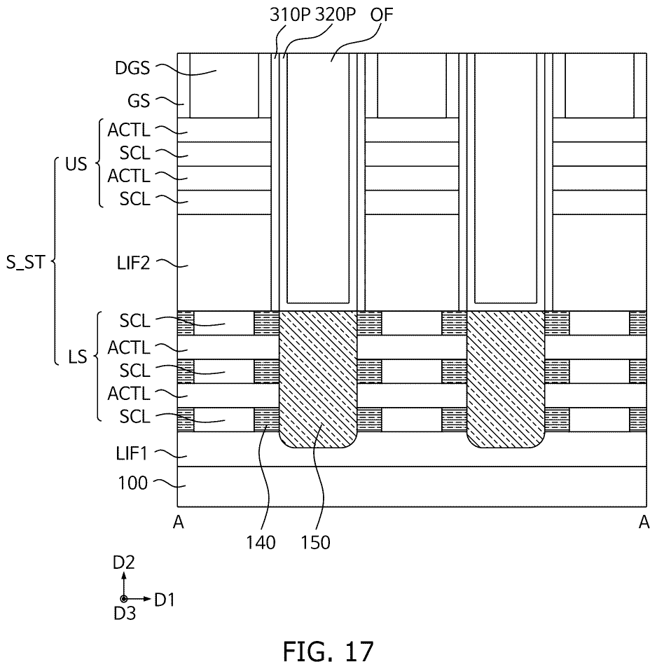

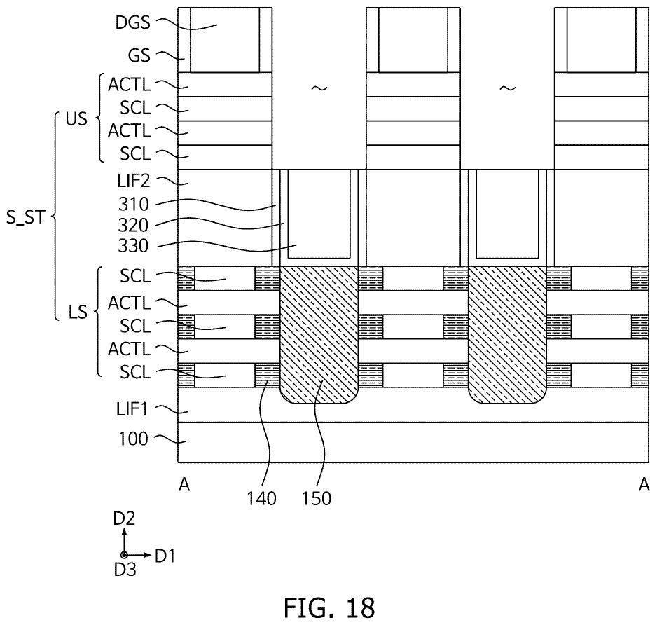

Referring to FIGS. 17 and 18, the first source/drain pattern 150 may be formed on a trench formed between the stacked structures S_ST, which have been patterned. A first preliminary etching stop film 320P may be formed on the first source/drain pattern 150 and the preliminary liner layer 310P, and an oxide film OF may be additionally formed thereon. Then, a portion of the preliminary liner layer 310P and the first preliminary etching stop film 320P may be respectively patterned to form the liner layer 310 and the first etching stop film 320. The oxide film OF may be eliminated during the process, and the first interlayer insulating film 330 may be formed in the resulting space.

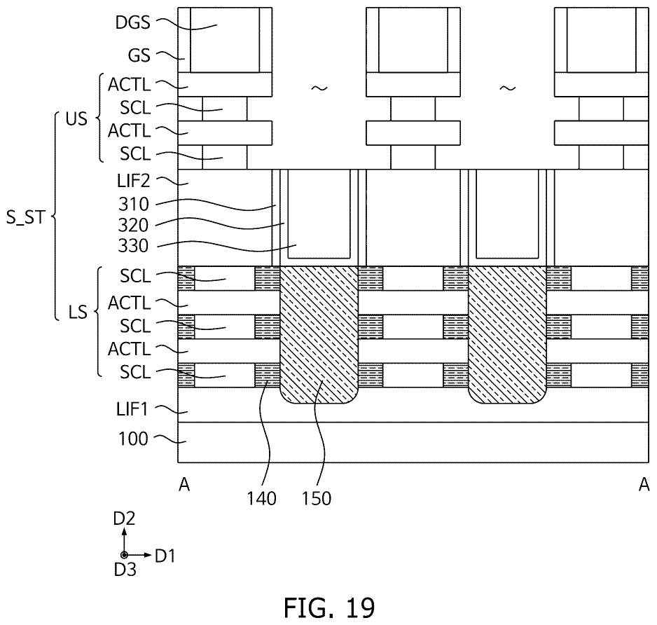

Referring to FIG. 19, a part of a side surface of the sacrificial semiconductor layer SCL of the stacked upper structure US may be selectively removed. Opposite side surfaces of the sacrificial semiconductor layer SCL of the stacked upper structure US may be partially patterned in the first direction D1.

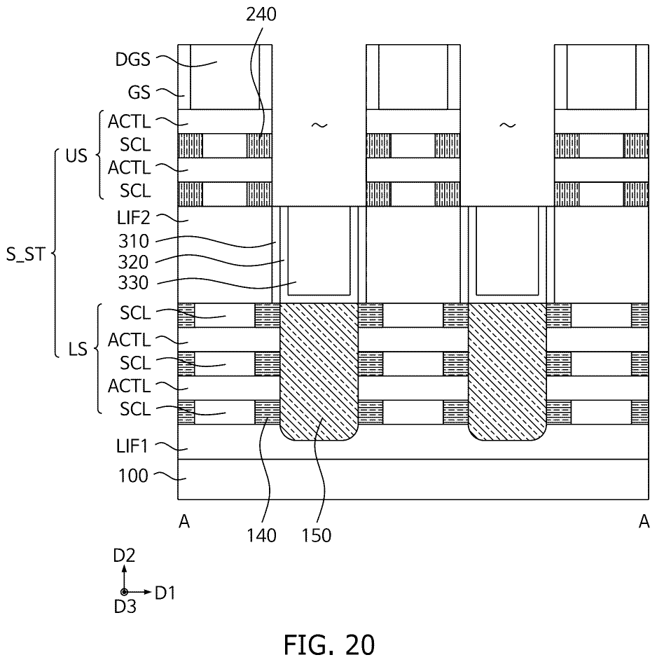

Referring to FIG. 20, the second internal spacer 240 may be formed in a space formed by partially removing the sacrificial semiconductor layer SCL of the stacked upper structure US in the first direction D1. The drawing shows an example in which a side surface of the second internal spacer 240 and a side surface of the active semiconductor layer ACTL of the stacked upper structure US are aligned with each other in the second direction D2, but the scope of the present disclosure is not limited thereto. For example, the side surface of the second internal spacer 240 may be formed at a position in the first direction D1 away from the position of the side surface of the active semiconductor layer ACTL of the stacked upper structure US. Here, the second internal spacer 240 may include tungsten oxide (WO₃), molybdenum oxide (MoO₃), silicon oxide (SiO₂), silicon nitride (Si₃N₄), hafnium silicate (HfSiO₄), or aluminum oxide (Al₂O₃). In other embodiments, the second internal spacer 240 may include aluminum oxide (Al₂O₃), hafnium oxide (HfO₂), zirconium oxide (ZrO₂), tantalum oxide (Ta₂O₃), or titanium oxide (TiO₂).

Then, a second source/drain pattern, e.g., the second source/drain pattern 250 in FIG. 2, may be formed between the stacked upper structures US, which have been patterned, the sacrificial semiconductor layer SCL of the stacked upper structure US and the stacked lower structure LS may be removed, and a gate electrode, e.g., the gate electrode 120 in FIG. 2, may be formed. Next, the gate insulating film 130 and the gate capping pattern GC may be formed. Through a manufacturing method identical or similar thereto, the semiconductor device described with reference to FIGS. 1 to 7, 9, and 10 may be provided.

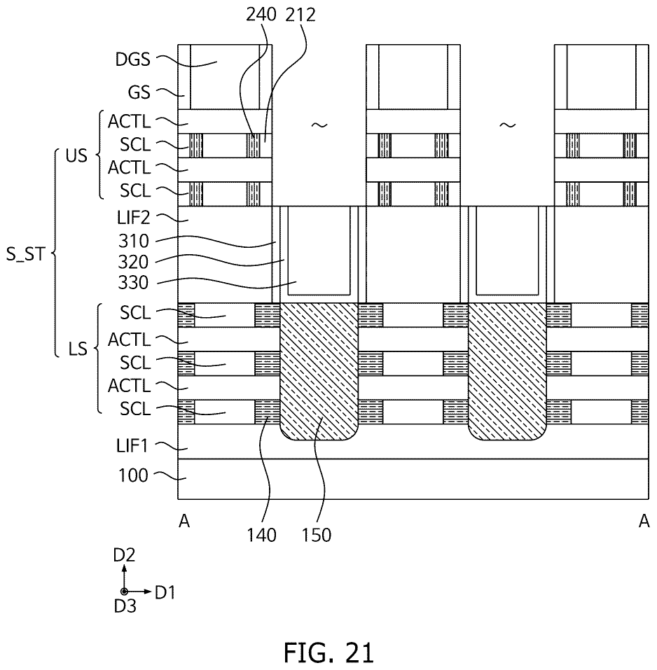

The method of manufacturing the semiconductor device described with reference to FIG. 8 may further include a step of forming the vertical channel pattern 212. For example, referring to FIG. 21, a part of the second internal spacer 240 may be converted to form the first vertical channel pattern 212. For a specific example, when the second internal spacer 240 is tungsten oxide (WO₃), a part thereof may be converted into tungsten selenide (WSe₂) through a selenization process, thereby forming the first vertical channel pattern 212. FIG. 21 illustrates a process of forming the first vertical channel pattern 212 of a second device, e.g., the second device 104 in FIG. 2, but the scope of the present disclosure is not limited thereto. In other embodiments, a portion of the first internal spacer 140 may be converted to form a second vertical channel pattern, e.g., the second vertical channel pattern 112 in FIG. 11. In this case, the method by which the second vertical channel pattern is formed may be identical or similar to the process by which the first vertical channel pattern 212 is formed. Then, a second source/drain pattern such as the second source/drain pattern 250 in FIG. 2, a gate electrode such as the gate electrode 120 in FIG. 2, the gate insulating film 130, and the gate capping pattern GC may be formed to provide the semiconductor device described with reference to FIGS. 8 and 11.

Although the present disclosure has been described by means of limited embodiments and drawings, it is not limited thereto. It is needless to say that, by a person having ordinary skill in the technical field to which the present disclosure belongs, various modifications and variations can be made to the present disclosure within the scope of the technology of the present disclosure and the claims set forth below.

1. A semiconductor device comprising:
a substrate;
a first transistor disposed on the substrate and comprising:
a plurality of first channel patterns stacked in a vertical direction perpendicular to an upper surface of the substrate, a first gate electrode surrounding each first channel pattern of the plurality of first channel patterns, a first internal spacer on a side surface of the first gate electrode and in a space between two adjacent first channel patterns, in the vertical direction, of the plurality of first channel patterns, and a first source/drain pattern adjacent to the plurality of first channel patterns in a horizontal direction parallel to the upper surface of the substrate; and
a second transistor stacked on the first transistor in the vertical direction and comprising a plurality of second channel patterns stacked in the vertical direction, a second gate electrode surrounding each second channel pattern of the plurality of second channel patterns, a second internal spacer on a side surface of the second gate electrode and disposed in a space between two adjacent second channel patterns, in the vertical direction, of the plurality of second channel patterns, and a second source/drain pattern adjacent to the plurality of second channel patterns in the horizontal direction,
wherein the plurality of first channel patterns and the plurality of second channel patterns comprise a two-dimensional material layer, and
wherein a material of the first internal spacer is different from a material of the second internal spacer.

2. The semiconductor device as claimed in claim 1,
wherein the two-dimensional material layer of the plurality of first channel patterns and the plurality of second channel patterns includes a metal chalcogenide material.

3. The semiconductor device as claimed in claim 1,
wherein a material of the first internal spacer includes aluminum oxide, and a material of the second internal spacer includes tungsten oxide or molybdenum oxide.

4. The semiconductor device as claimed in claim 1,
wherein the first transistor is an n-type transistor,
wherein the second transistor is a p-type transistor, and
wherein the second transistor further comprises a vertical channel pattern in a space between the second source/drain pattern and the second internal spacer in the horizontal direction.

5. The semiconductor device as claimed in claim 4,
wherein a material of the plurality of second channel patterns is the same as a material of the vertical channel pattern.

6. The semiconductor device as claimed in claim 1,
wherein a length, in the horizontal direction, of each first channel pattern of the plurality of first channel patterns is longer than a length, in the horizontal direction, of each second channel pattern of the plurality of second channel patterns.

7. The semiconductor device as claimed in claim 1,
wherein the first internal spacer includes tungsten oxide or molybdenum oxide, and
wherein the second internal spacer includes aluminum oxide.

8. The semiconductor device as claimed in claim 1,
wherein the first transistor is a p-type device,
wherein the second transistor is an n-type device, and
wherein the first transistor further comprises a vertical channel pattern in a space between the first source/drain pattern and the first internal spacer in the horizontal direction.

9. The semiconductor device as claimed in claim 8,
wherein a material of the plurality of first channel patterns is the same as a material of the vertical channel pattern.

10. The semiconductor device as claimed in claim 1, further comprising:
a first level isolation insulating film under the first transistor,
wherein the first level isolation insulating film contacts the first source/drain pattern, the first gate electrode, and the first internal spacer.

11. The semiconductor device as claimed in claim 1, further comprising:
a second level isolation insulating film in a space between the plurality of first channel patterns and the plurality of second channel patterns in the vertical direction.

12. The semiconductor device as claimed in claim 11, further comprising:
an interlayer insulating film in a space between the first source/drain pattern and the second source/drain pattern in the vertical direction; and
a liner layer in a space between the second level isolation insulating film and the interlayer insulating film in the horizontal direction.

13. The semiconductor device as claimed in claim 1,
wherein a width of the first source/drain pattern is smaller than a width of the second source/drain pattern.

14. The semiconductor device as claimed in claim 1,
wherein the first source/drain pattern includes a first portion having a first width at a first vertical level corresponding to a corresponding portion of the first gate electrode and a second portion having a second width at a second vertical level corresponding to a corresponding first channel pattern of the plurality of first channel patterns,
wherein the first portion and the corresponding portion of the first gate electrode are adjacent to each other in the horizontal direction at the first vertical level,
wherein the second portion and the corresponding first channel pattern are adjacent to each other in the horizontal direction at the second vertical level, and
wherein the first width is larger than the second width.

15. The semiconductor device as claimed in claim 1,
wherein the first source/drain pattern and the second source/drain pattern include metal.

16. A semiconductor device comprising:
a substrate;
a first transistor disposed on the substrate and comprising a plurality of first channel patterns stacked in a vertical direction perpendicular to an upper surface of the substrate, a first gate electrode surrounding each first channel pattern of the plurality of first channel patterns, and a first internal spacer on a side surface of the first gate electrode and in a space between two adjacent first channel patterns, in the vertical direction, of the plurality of first channel patterns; and
a second transistor stacked on the first transistor in the vertical direction and comprising a plurality of second channel patterns stacked in the vertical direction, a second gate electrode surrounding each second channel pattern of the plurality of second channel patterns, and a second internal spacer on a side surface of the second gate electrode and in a space between two adjacent second channel patterns, in the vertical direction, of the plurality of second channel patterns,
wherein the plurality of first channel patterns and the plurality of second channel patterns comprise a two-dimensional material layer, and
wherein a material of the first internal spacer is a first metal oxide and a material of the second internal spacer is a second metal oxide different from the first metal oxide.

17. The semiconductor device as claimed in claim 16,
wherein a first length of each first channel pattern of the plurality of first channel patterns is longer than a second length of each second channel pattern of the plurality of second channel patterns, and
wherein each of the first length and the second length is measured in a horizontal direction parallel to the upper surface of the substrate.

18. The semiconductor device as claimed in claim 16,
wherein the first transistor is an n-type transistor,
wherein the second transistor is a p-type transistor,
wherein the second transistor further comprises a vertical channel pattern extending in the vertical direction, and
wherein the vertical channel pattern is disposed in a space between two adjacent second channel patterns, in the vertical direction, of the plurality of second channel patterns.

19. The semiconductor device as claimed in claim 16,
wherein the first transistor is a p-type transistor,
wherein the second transistor is an n-type transistor,
wherein the first transistor further comprises a vertical channel pattern extending in the vertical direction, and
wherein the vertical channel pattern is disposed in a space between two adjacent first channel patterns, in the vertical direction, of the plurality of first channel patterns.

20. A semiconductor device comprising:
a substrate;
a first transistor disposed on the substrate and comprising a plurality of first channel patterns stacked in a vertical direction perpendicular to an upper surface of the substrate, a first gate electrode surrounding each first channel pattern of the plurality of first channel patterns, a first internal spacer on a side surface of the first gate electrode and in a space between two adjacent first channel patterns, in the vertical direction, of the plurality of first channel patterns, and a first source/drain pattern adjacent to the plurality of first channel patterns in a horizontal direction parallel to the upper surface of the substrate;
a second transistor stacked on the first transistor and comprising a plurality of second channel patterns stacked in the vertical direction, a second gate electrode surrounding each second channel pattern of the plurality of second channel patterns, a second internal spacer on a side surface of the second gate electrode and in a space between two adjacent second channel patterns, in the vertical direction, of the plurality of second channel patterns, and a second source/drain pattern adjacent to the plurality of second channel patterns in the horizontal direction;
a first level isolation insulating film disposed in a space between the upper surface of the substrate and each of the first source/drain pattern, the first gate electrode, and the first internal spacer in the vertical direction;
a second level isolation insulating film disposed in a space between the plurality of first channel patterns and the plurality of second channel patterns in the vertical direction;
an interlayer insulating film in a space between the first source/drain pattern and the second source/drain pattern in the vertical direction; and
a liner layer disposed in a space between the second level isolation insulating film and the interlayer insulating film in the horizontal direction,
wherein the plurality of first channel patterns and the plurality of second channel patterns comprise a two-dimensional material layer, and
wherein the first internal spacer and the second internal spacer include different materials.
